(19) United States
(12) Patent Application Publication
(10) Pub. No.: US 2026/0362997 A1
(43) Pub. Date: Nov. 12, 2026

(54) METHOD FOR IMPROVING ETCH SELECTIVTY OF SILICON NITRIDE

(71) Applicant: Tokyo Electron Limited, Tokyo (JP)

(72) Inventors: Du Zhang, Albany, NY (US); Yu Hao Tsai, Albany, NY (US)

(21) Appl. No.: 19/205,071

(22) Filed: May 12, 2025

(51) Int. Cl. H10P 50/28; H10P 14/60

(52) U.S. Cl. CPC H10P 50/283; H10P 14/6518; H10P 14/6532

(57) ABSTRACT

A method includes performing a hydrogen treatment process on a silicon nitride layer formed on a substrate. The hydrogen treatment process forming a hydrogen-rich silicon nitride layer. The method further includes performing a fluorine treatment process to convert the hydrogen-rich silicon nitride layer into an ammonium fluorosilicate layer and performing a plasma process to remove the ammonium fluorosilicate layer.

### TECHNICAL FIELD

The present disclosure relates generally to methods of processing a substrate, and, in particular embodiments, to methods for improving an etch selectively of silicon nitride.

### BACKGROUND

Semiconductor device manufacturing relies on precise control of material deposition and removal to create intricate structures with specific dimensions and properties. As device scaling continues to advance, the demands for precise and selective material etching have become increasingly stringent. Silicon nitride is a commonly used material in semiconductor fabrication due to its excellent dielectric properties, chemical resistance, and thermal stability.

In modern semiconductor devices, silicon nitride layers serve various functions including spacers, diffusion barriers, and etch stops. The ability to selectively remove silicon nitride while preserving other materials such as silicon dioxide, silicon, titanium nitride, and carbon-based masks is important for many fabrication processes.

### SUMMARY

In accordance with an embodiment, a method includes: performing a hydrogen treatment process on a silicon nitride layer formed on a substrate, the hydrogen treatment process forming a hydrogen-rich silicon nitride layer; performing a fluorine treatment process to convert the hydrogen-rich silicon nitride layer into an ammonium fluorosilicate layer; and performing a plasma process to remove the ammonium fluorosilicate layer.

In accordance with another embodiment, a method includes: performing a first hydrogen treatment process on a silicon nitride layer formed on a substrate, the first hydrogen treatment process forming a first hydrogen-rich silicon nitride layer; performing a first fluorine treatment process to convert a first portion of the first hydrogen-rich silicon nitride layer into a first ammonium fluorosilicate layer; performing a first plasma process to remove the first ammonium fluorosilicate layer; determining whether a second hydrogen treatment process is needed; and in response to determining that the second hydrogen treatment process is not needed: performing a second fluorine treatment process to convert a second portion of the first hydrogen-rich silicon nitride layer into a second ammonium fluorosilicate layer; and performing a second plasma process to remove the second ammonium fluorosilicate layer.

In accordance with yet another embodiment, A method includes: performing an etch process on a silicon nitride layer formed on a substrate, the etch process including one or more cycles, where a first cycle of the etch process includes: performing a hydrogen (H₂) plasma process on the silicon nitride layer to form a hydrogen-rich silicon nitride layer; performing a hydrogen fluoride (HF) treatment process to convert the hydrogen-rich silicon nitride layer into an ammonium fluorosilicate layer; and performing an argon (Ar) plasma process to remove the ammonium fluorosilicate layer.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1G illustrate cross-sectional views of intermediate stages in the manufacturing of a semiconductor structure, in accordance with various embodiments;

FIG. 2 illustrates a table showing computed adsorption energies of HF molecule on various surfaces, in accordance with various embodiments;

FIG. 3 illustrates a flow diagram of a method for selectively etching a silicon nitride layer, in accordance with various embodiments;

FIG. 4 illustrates a flow diagram of a method for selectively etching a silicon nitride layer, in accordance with various embodiments; and

FIG. 5 illustrates a flow diagram of a method for selectively etching a silicon nitride layer, in accordance with various embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Aspects of the present disclosure relate to methods for selectively etching silicon nitride with enhanced precision and control. In various embodiments, a gas-dosing atomic layer etching (ALE) process provides atomic-level precision for silicon nitride removal while maintaining high selectivity against other materials such as silicon dioxide, silicon, and titanium nitride. The process can include performing a hydrogen treatment process on a silicon nitride layer to form a hydrogen-rich silicon nitride surface, performing a fluorine treatment process with the plasma off to convert the hydrogen-rich silicon nitride into an ammonium fluorosilicate layer, and performing a plasma process to remove the converted layer. The hydrogen treatment process can enhance the adsorption of the fluorine-containing etchant on the silicon nitride surface while maintaining weak adsorption on other materials, thereby improving selectivity.

In one or more embodiments, the hydrogen treatment process may be performed using a remote hydrogen plasma, which can generate atomic hydrogen that modifies the silicon nitride surface. The fluorine treatment process may utilize hydrogen fluoride (HF) gas without plasma activation, which can selectively adsorb onto the hydrogen-rich silicon nitride surface. The plasma process for removing the converted layer may use an argon plasma with controlled bias voltage to volatilize the ammonium fluorosilicate layer into volatile byproducts.

In various embodiments, the process may be performed in one or more cycles, with options for performing the hydrogen treatment process in every cycle or only in the first cycle. The process may also include in-situ monitoring of the surface hydrogen content to determine whether additional hydrogen treatment is needed. The temperature range for the process may be controlled to optimize the reaction efficiency and selectivity. The disclosed method may provide advantages including precise control of etch depth, minimal damage to underlying layers, enhanced selectivity against various materials, anisotropic etching capability, and the use of environmentally friendly etchants with low global warming potential. These and additional details are further discussed below.

While the various embodiments of the present disclosure are described in the context of silicon nitride etching for semiconductor device fabrication, it should also be appreciated that these embodiments may also apply to etching of other dielectric materials and nitride compounds. In particular, aspects of this disclosure may similarly apply to selective etching of silicon oxynitride (SiON), silicon carbonitride (SiCN), silicon borocarbonitride (SiBCN), boron nitride, and other nitride-containing materials used in various microelectronic, optical, and microelectromechanical systems (MEMS) applications.

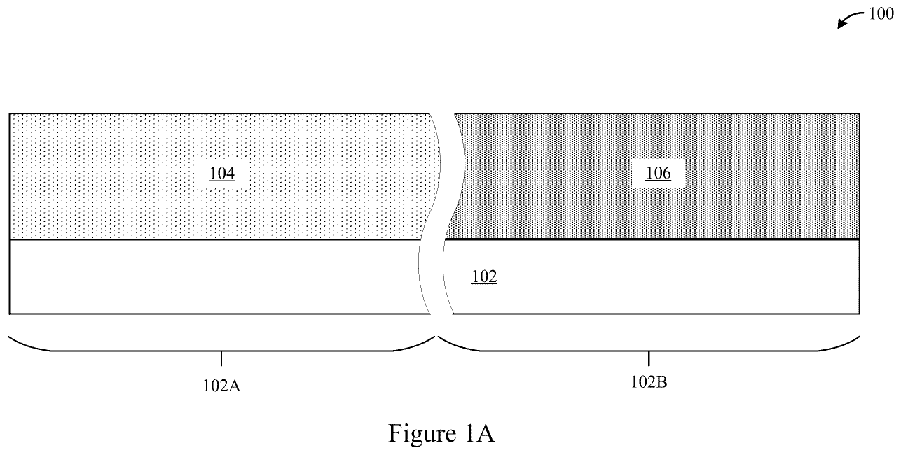

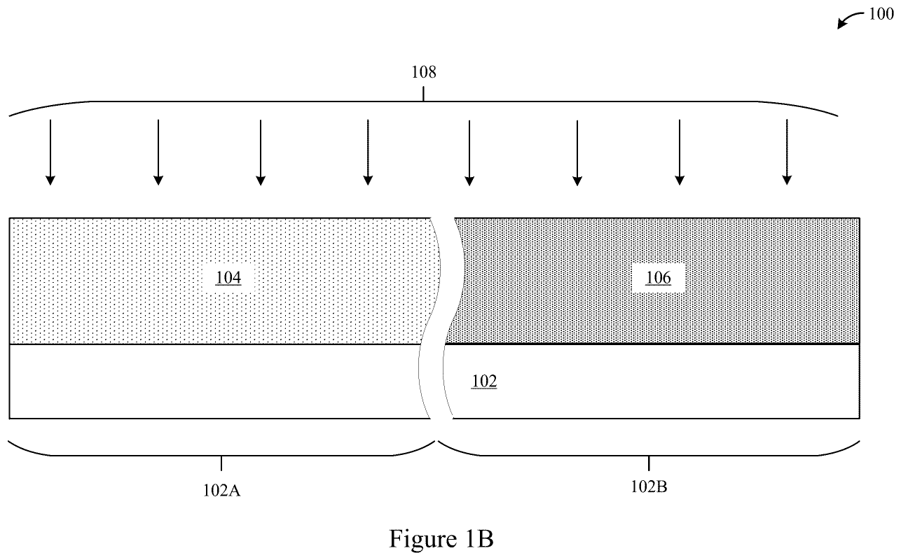

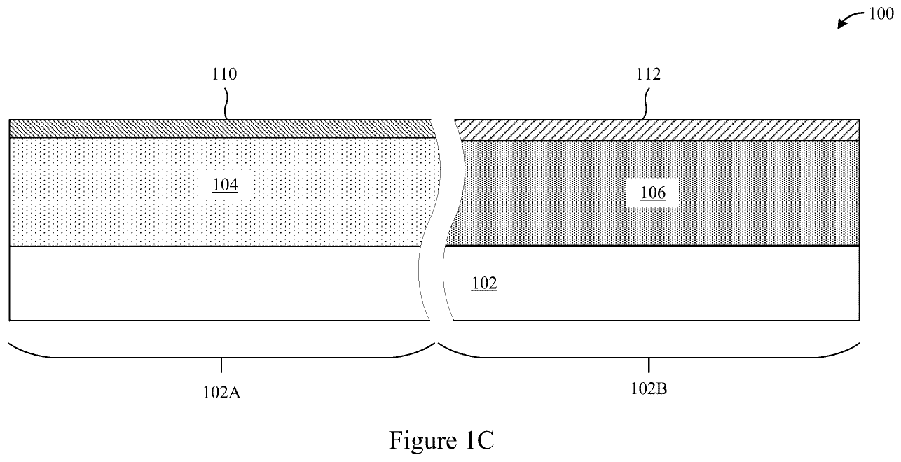

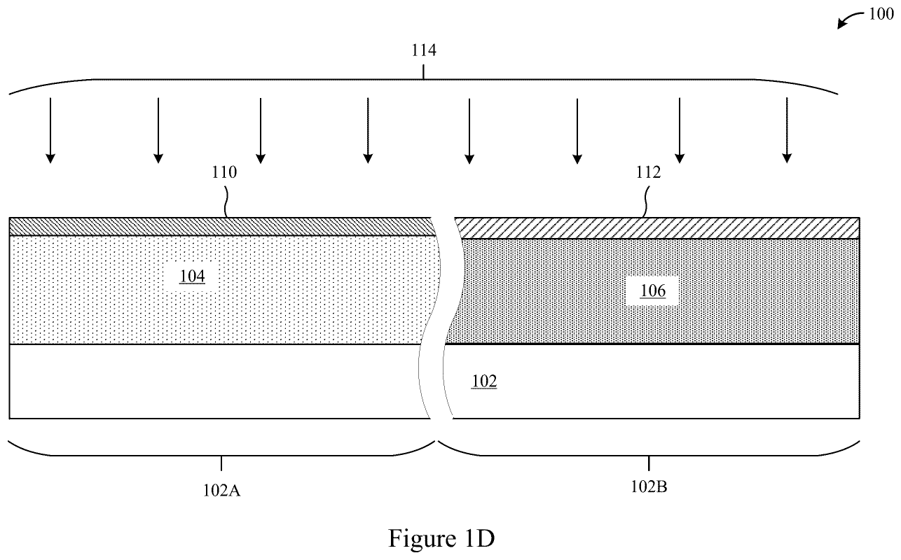

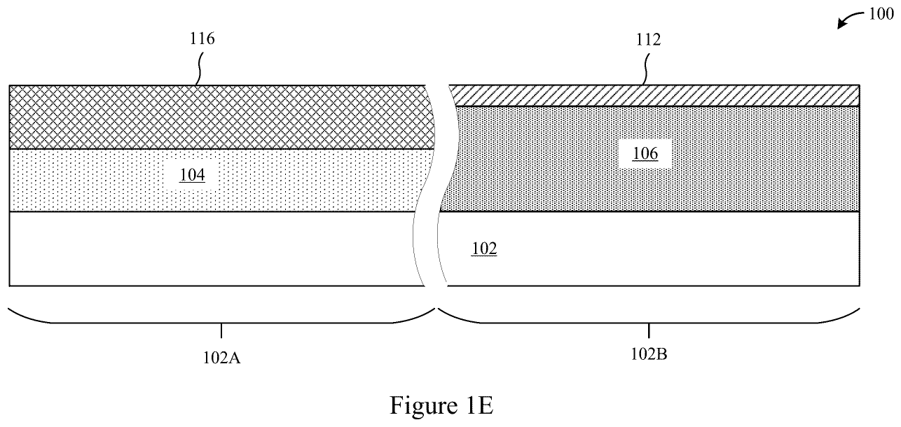

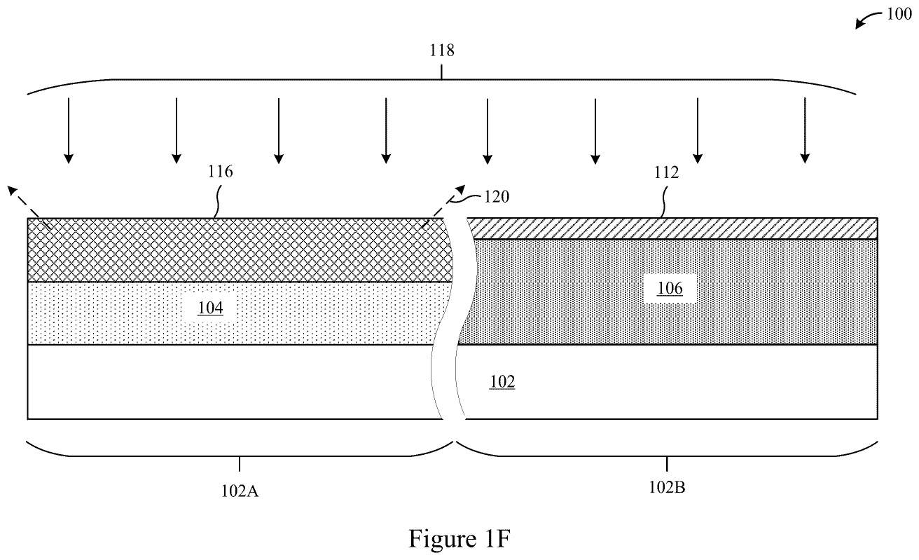

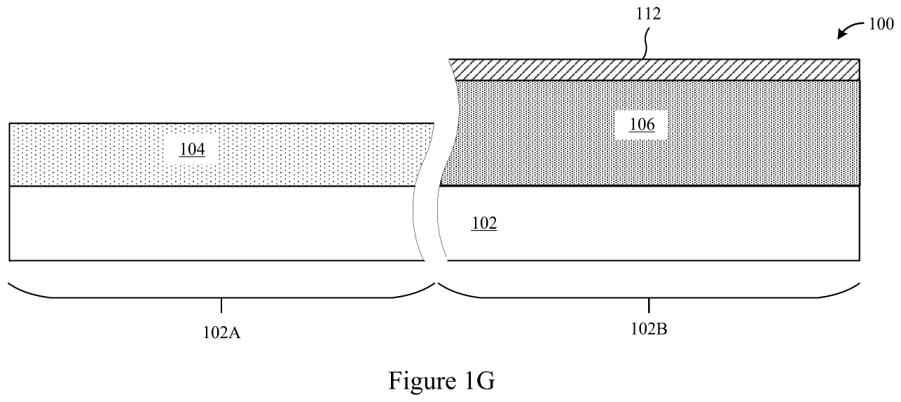

FIGS. 1A-1G illustrate cross-sectional views of intermediate stages in the manufacturing of a semiconductor structure 100, in accordance with various embodiments. FIG. 1A illustrates the semiconductor structure 100 at an initial stage of a selective silicon nitride etching process. The semiconductor structure 100 includes a substrate 102 with regions 102A and 102B, which may represent different device regions or different materials. Region 102A may represent, for example, an active device region, while region 102B may represent an isolation region or another type of device region. The specific configuration and composition of regions 102A and 102B can vary depending on the particular semiconductor device being fabricated. In one embodiment, the region 102A is in physical contact with the region 102B. In another embodiment, the region 102A is spatially separated from the region 102B.

In some embodiments, the substrate 102 may include a semiconductor material such as silicon, silicon germanium, silicon carbide, gallium arsenide, or other suitable semiconductor materials. In other embodiments, substrate 102 may comprise heterogeneous layers such as silicon germanium on silicon, gallium nitride on silicon, silicon carbon on silicon, or layers of silicon on a silicon or silicon-on-insulator (SOI) substrate. In various embodiments, the substrate 102 may include previously formed device structures such as transistors, capacitors, resistors, or other circuit elements formed during front-end-of-line (FEOL) processing. In such embodiments, the substrate 102 may include various doped regions, isolation structures, and other semiconductor components that form part of an integrated circuit.

The semiconductor structure 100 further includes a dielectric layer 104 formed over the substrate 102 in the region 102A. In an embodiment, the dielectric layer 104 comprises silicon nitride (Si₃N₄), which is the target material for the selective etching process described in subsequent figures. The dielectric layer 104 may be formed using deposition techniques such as chemical vapor deposition (CVD), plasma-enhanced chemical vapor deposition (PECVD), atomic layer deposition (ALD), combinations thereof, or other suitable deposition methods. The thickness of the dielectric layer 104 may vary depending on the specific application, ranging from a few nanometers to several hundred nanometers.

The semiconductor structure 100 also includes a layer 106 formed over the substrate 102 in the region 102B. In some embodiments, a portion of the dielectric layer 104 may be over and in physical contact with the layer 106. In other embodiments, a portion of the layer 106 may be over and in physical contact with the dielectric layer 104. In various embodiments, the layer 106 may comprise a material that has selectivity (e.g., reduced etch rate) with respect to the dielectric layer 104 during the etching process, such as silicon dioxide (SiO₂), silicon (Si), titanium nitride (TiN), a carbon-based mask material, combinations thereof, or the like. The layer 106 may be formed using deposition techniques such as physical vapor deposition (PVD), CVD, PECVD, ALD, combinations thereof, or other suitable deposition methods. The layer 106 may function as a mask for the subsequent selective etching of the dielectric layer 104, or it may be another functional layer in the semiconductor device structure that needs to be preserved during the etching process.

In FIG. 1B, a hydrogen treatment process 108 is applied to the structure shown in FIG. 1A to modify the surface properties of the dielectric layer 104 prior to the subsequent etching steps. In one or more embodiments, the hydrogen treatment process 108 comprises exposing the semiconductor structure 100 to a hydrogen plasma, for example, a remote hydrogen plasma. The hydrogen plasma generates atomic hydrogen species that interact with the surface of the dielectric layer 104, creating a hydrogen-rich surface. The hydrogen plasma may be generated in a plasma chamber using hydrogen gas (H₂) as a precursor, with the hydrogen plasma being remotely generated to minimize plasma-induced damage to the semiconductor structure 100. In some embodiments, the plasma chamber may be an inductively-coupled plasma (ICP) chamber, a capacitively-coupled plasma (CCP) chamber, or the like.

The hydrogen treatment process 108 is designed to enhance the subsequent adsorption of fluorine-containing etchants on the dielectric layer 104 while maintaining weak adsorption on other materials such as the layer 106. In embodiments when the dielectric layer 104 comprises silicon nitride, the hydrogen treatment process 108 creates N—H and Si—H bonds on the silicon nitride surface, which decreases the adsorption energy of HF molecules compared to untreated silicon nitride or other materials.

The hydrogen treatment process 108 may be performed at a temperature in a range from −20 °C to 100 °C and at a pressure in a range from 5 mTorr to 500 mTorr. The duration of the hydrogen treatment process may vary depending on the desired degree of surface modification, and may range from a few seconds to several minutes. The process parameters, including plasma power, pressure, temperature, and duration, can be tuned to achieve the desired surface modification while minimizing any potential damage to the semiconductor structure 100.

FIG. 1C illustrates the semiconductor structure 100 including a hydrogen-rich layer 110 formed at the surface of the original dielectric layer 104 as a result of the hydrogen treatment process 108 shown in FIG. 1B. In one or more embodiments, the hydrogen-rich layer 110 represents a modified surface region of the dielectric layer 104 where hydrogen atoms have been incorporated into the dielectric material (e.g., silicon nitride) of the dielectric layer 104. In embodiments when the dielectric layer 104 comprises silicon nitride, the hydrogen-rich layer 110 comprises hydrogen-rich silicon nitride. In such embodiments, the hydrogen-rich layer 110 comprises an increased concentration of N—H and Si—H bonds compared to the untreated silicon nitride. The thickness of the hydrogen-rich layer 110 may vary depending on process parameters of the hydrogen treatment process 108 (see FIG. 1B), and may be in a range from several angstroms to 10's of nanometers.

The hydrogen-rich layer 110 exhibits different chemical properties compared to the underlying dielectric layer 104, particularly in terms of its interaction with fluorine-containing etchants. In embodiments when the dielectric layer 104 comprises silicon nitride, the hydrogen-rich silicon nitride surface has a lower adsorption energy for HF molecules, resulting in improved absorption of fluorine-containing etchants.

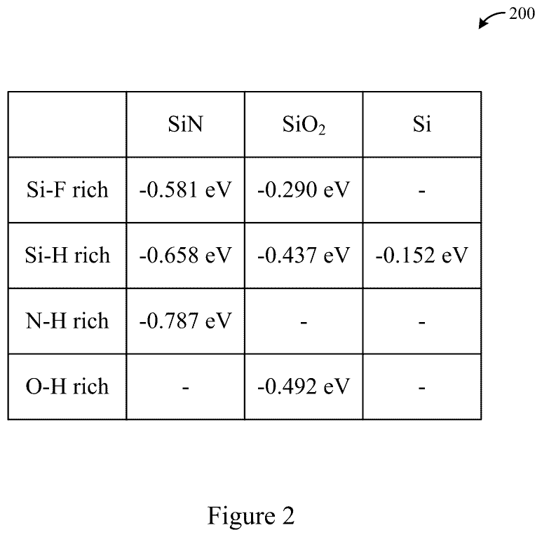

As illustrated in Table 200 of FIG. 2, which shows density functional theory (DFT) calculations of adsorption energies of HF molecule on various surfaces, N—H rich silicon nitride surfaces have an adsorption energy of −0.787 eV, Si—H rich silicon nitride surfaces have an adsorption energy of −0.658 eV, and Si—F rich silicon nitride surfaces have an adsorption energy of −0.581 eV. In contrast, other materials show higher adsorption energies. As further shown in Table 200 of FIG. 2, Si—H rich silicon surfaces have an adsorption energy of −0.152 eV, Si—F rich silicon dioxide surfaces have an adsorption energy of −0.290 eV, Si—H rich silicon dioxide surfaces have an adsorption energy of −0.437 eV, and O—H rich silicon dioxide surfaces have an adsorption energy of −0.492 eV. This difference in adsorption energy allows for achieving selective etching in subsequent steps.

The hydrogen treatment process 108 (see FIG. 1B) also affects layer 106, creating a hydrogen-rich layer 112 on the exposed surfaces of layer 106. However, the effect of hydrogen treatment on layer 106 differs from its effect on the dielectric layer 104. In embodiments when the layer 106 comprises silicon dioxide, or silicon, the hydrogen treatment may terminate dangling bonds on these surfaces, which reduces the adsorption of fluorine-containing etchants (e.g., HF) as shown in Table 200 of FIG. 2.

In FIG. 1D, a fluorine treatment process 114 is applied to the structure shown in FIG. 1C to modify the properties of the hydrogen-rich layer 110. In one or more embodiments, the fluorine treatment process 114 comprises exposing the semiconductor structure 100 to a fluorine-containing gas, such as hydrogen fluoride (HF) gas, without plasma activation. The plasma-off approach may prevent the dissociation of HF molecules in the gas phase, which would create reactive fluorine radicals that could react non-selectively with various materials. Instead, the intact HF molecules selectively adsorb onto the hydrogen-rich silicon nitride surface based on the different adsorption energies discussed previously. The fluorine treatment process 114 may be performed at a temperature in a range from −20 °C to 100 °C, a pressure in a range from 5 mTorr to 500 mTorr, and a duration in a range from a few seconds to several minutes. The HF gas has a lower global warming potential (GWP) compared to conventional etchants for silicon nitride, such as hydrofluorocarbons (HFCs), which allows for improved sustainability.

During the fluorine treatment process 114, the HF molecules adsorb onto the hydrogen-rich layer 110 and undergo a spontaneous chemical reaction to form a converted layer 116 as illustrated in FIG. 1E. In embodiments when the hydrogen-rich layer 110 comprises the hydrogen-rich silicon nitride, the spontaneous chemical reaction forms an ammonium fluorosilicate compound. The temperature of the fluorine treatment process 114 plays an important role in the reaction kinetics. At higher temperatures in a range from −20 °C to 100 °C, the spontaneous chemical reaction may achieve more complete conversion of the hydrogen-rich silicon nitride into ammonium fluorosilicate. At lower temperatures below −20 °C, the conversion may be slower or incomplete, potentially reducing the overall etch rate.

The spontaneous chemical reaction is energetically favorable on the hydrogen-rich silicon nitride surface but not on the hydrogen-rich surfaces of other materials such as silicon dioxide or silicon due to the differences in adsorption energies (see Table 200 of FIG. 2). Accordingly, the HF molecules that contact the hydrogen-rich layer 112 on layer 106 have a much lower probability of adsorption and reaction, which contributes to the high selectivity of the etching process. The hydrogen-rich layer 112 remains largely unchanged during the fluorine treatment process 114 due to the weak interaction between HF and the hydrogen-rich layer 112.

FIG. 1E illustrates the semiconductor structure 100 including the converted layer 116 formed at the surface of the original dielectric layer 104 as a result of the fluorine treatment process 114 shown in FIG. 1D. In one or more embodiments, the converted layer 116 comprises the ammonium fluorosilicate compound having a chemical composition (NH₄)₂SiF₆. The formation of ammonium fluorosilicate is a self-limiting reaction at the surface of the silicon nitride, which contributes to the precision of the etching process. Once the surface layer is converted to ammonium fluorosilicate, the reaction rate significantly decreases as HF molecules must diffuse through the converted layer to reach unreacted silicon nitride. This self-limiting behavior allows atomic-level control over the amount of material removed in each cycle of the etching process.

The converted layer 116 has different physical and chemical properties compared to the original dielectric layer 104. In some embodiments, the converted layer 116 is less dense and more susceptible to removal by physical processes such as ion bombardment, allowing for its removal without liquid etchants.

In FIG. 1F, the semiconductor structure 100 undergoes a plasma process 118 to remove the converted layer 116. In an embodiment, the plasma process 118 comprises exposing the semiconductor structure 100 to an argon (Ar) plasma. In other embodiments, the plasma process 118 may comprise exposing the semiconductor structure 100 to a plasma generated from an inert gas such as helium (He), neon (Ne), krypton (Kr), or xenon (Xe). The plasma of the plasma process 118 provides ion bombardment that helps to volatilize the converted layer 116, converting it into volatile byproducts 120 that can be pumped away from the process chamber. In some embodiments, the plasma process 118 may be a CCP plasma process, or the like.

The plasma process 118 may be controlled to allow for selective removal of only the converted layer 116 without damaging the underlying dielectric layer 104, the hydrogen-rich layer 112, or the layer 106. In various embodiments, a bias voltage that is applied during the plasma process 118 is maintained below 100 V and a pulsed directed current (DC) bias waveform is used for narrow ion energy distribution control. The ion energy distribution control ensures that ion bombardment is sufficient to remove the converted layer 116 but not energetic enough to cause significant sputtering of the underlying dielectric layer 104, the hydrogen-rich layer 112, or the layer 106. In embodiments when the converted layer 116 comprises ammonium fluorosilicate, during the plasma process 118, ammonium fluorosilicate decomposes into volatile byproducts 120 including silicon tetrafluoride (SiF₄), hydrogen fluoride (HF), and ammonia (NH₃).

FIG. 1G illustrates a resulting structure after the plasma process 118 (see FIG. 1F) has removed the converted layer 116, leaving a new surface of the dielectric layer 104. In some embodiments, the process described with reference to FIGS. 1A-1G comprises one cycle of the etching process resulting in the removal of a thin layer of the original dielectric layer 104, on the order of a few angstroms to a few nanometers depending on the process parameters. The surface of the dielectric layer 104 is now exposed and ready for another etching cycle if additional material removal is desired. The layer 106 remains largely unchanged after the etching cycle, demonstrating the high selectivity of the etching process.

After completing one cycle, the process may be repeated multiple times to achieve the desired etch depth. In various embodiments, subsequent cycles may follow different paths: (1) returning to the hydrogen treatment step to refresh the hydrogen-rich surface before the next fluorine treatment, or (2) proceeding directly to another fluorine treatment if the surface still contains sufficient hydrogen to promote selective HF adsorption. The decision between these paths may be based on predetermined process recipes or on in-situ monitoring of the surface hydrogen content using techniques such as Fourier transform infrared spectroscopy (FTIR), or the like. This cyclic approach allows for precise layer-by-layer removal of silicon nitride with enhanced control over etch depth and selectivity against other materials.

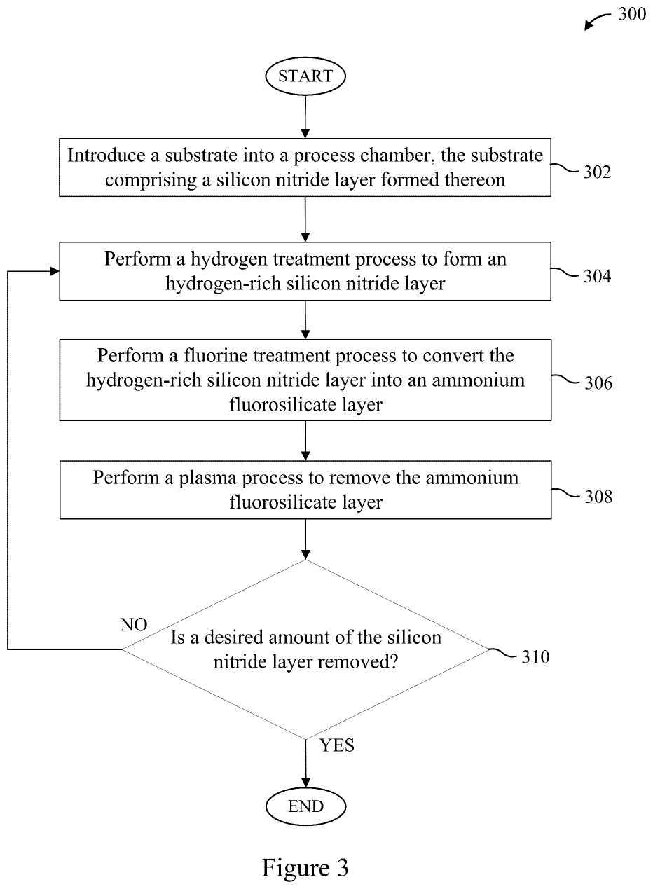

FIG. 3 illustrates a flow diagram of a method 300 for selectively etching a silicon nitride layer, in accordance with various embodiments. Although shown in a particular sequence, it should be appreciated that the steps of the method 300 may be performed in any suitable sequence.

In step 302, a substrate (e.g., substrate 102 of FIG. 1A) comprising a silicon nitride layer (e.g., dielectric layer 104 of FIG. 1A) formed thereon is introduced into a process chamber. The process chamber may be configured for various plasma processes and gas treatments, and may include components for temperature control, pressure regulation, and gas delivery.

In step 304, a hydrogen treatment process (e.g., hydrogen treatment process 108 of FIG. 1B) is performed on the silicon nitride layer to form a hydrogen-rich silicon nitride layer (e.g., hydrogen-rich layer 110 of FIG. 1C), as described above with refence to FIGS. 1B and 1C.

In step 306, a fluorine treatment process (e.g., fluorine treatment process 114 of FIG. 1D) is performed to convert the hydrogen-rich silicon nitride layer into an ammonium fluorosilicate layer (e.g., converted layer 116 of FIG. 1E), as described above with refence to FIGS. 1D and 1E.

In step 308, a plasma process (e.g., plasma process 118 of FIG. 1F) is performed to remove the ammonium fluorosilicate layer, as described above with refence to FIGS. 1F and 1G.

In some embodiments, steps 304-308 may be performed in a same process chamber. In other embodiments, at least one of steps 304-308 may be performed in a deferent process chamber than the rest of steps 304-308.

In step 310, the method 300 determines whether a desired amount of the silicon nitride layer has been removed. The decision may be based on predetermined process recipes specifying a fixed number of cycles, or it may involve in-situ monitoring techniques such as optical emission spectroscopy to detect when etching of the silicon nitride is complete. In response to determining at step 310 that the desired amount of the silicon nitride layer has not been removed, the method 300 proceeds back to step 304 to perform another cycle of etching. In response to determining at step 310 that the desired amount of the silicon nitride layer has been removed, the method 300 ends.

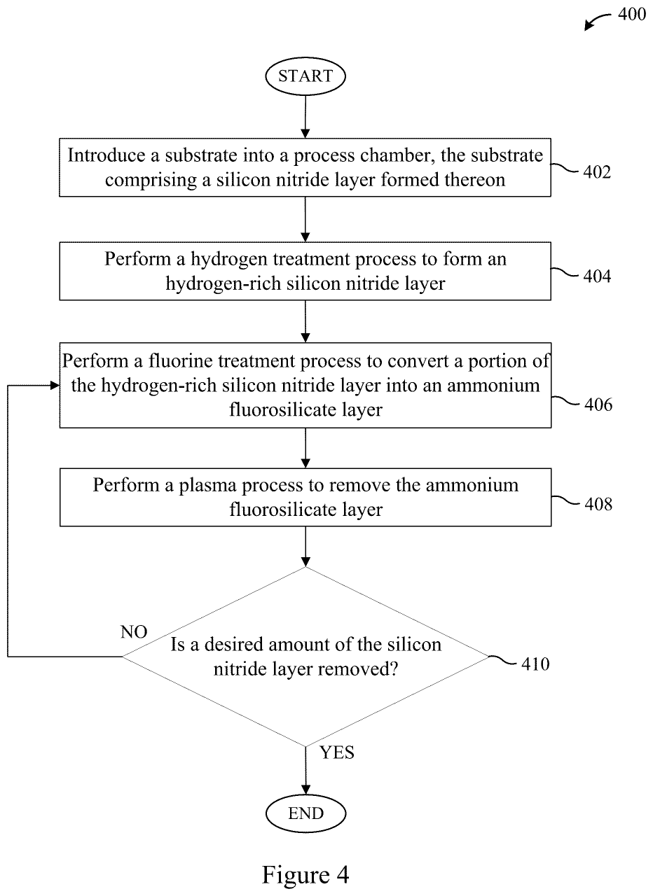

FIG. 4 illustrates a flow diagram of a method 400 for selectively etching a silicon nitride layer, in accordance with various embodiments. Although shown in a particular sequence, it should be appreciated that the steps of the method 400 may be performed in any suitable sequence.

In step 402, a substrate (e.g., substrate 102 of FIG. 1A) comprising a silicon nitride layer (e.g., dielectric layer 104 of FIG. 1A) formed thereon is introduced into a process chamber. The process chamber may be configured for various plasma processes and gas treatments, and may include components for temperature control, pressure regulation, and gas delivery.

In step 404, a hydrogen treatment process (e.g., hydrogen treatment process 108 of FIG. 1B) is performed on the silicon nitride layer to form a hydrogen-rich silicon nitride layer (e.g., hydrogen-rich layer 110 of FIG. 1C), as described above with refence to FIGS. 1B and 1C.

In step 406, a fluorine treatment process (e.g., fluorine treatment process 114 of FIG. 1D) is performed to convert a portion of the hydrogen-rich silicon nitride layer into an ammonium fluorosilicate layer (e.g., converted layer 116 of FIG. 1E), as described above with refence to FIGS. 1D and 1E. Step 406 is similar to step 306 in the method 300, with the distinction that only a portion of the hydrogen-rich silicon nitride layer is converted in each cycle, potentially allowing for multiple fluorine treatment cycles without requiring additional hydrogen treatment steps.

In step 408, a plasma process (e.g., plasma process 118 of FIG. 1F) is performed to remove the ammonium fluorosilicate layer, as described above with refence to FIGS. 1F and 1G.

In some embodiments, steps 404-408 may be performed in a same process chamber. In other embodiments, at least one of steps 404-408 may be performed in a deferent process chamber than the rest of steps 404-408.

In step 410, the method 400 determines whether a desired amount of the silicon nitride layer has been removed. The decision may be based on predetermined process recipes specifying a fixed number of cycles, or it may involve in-situ monitoring techniques such as optical emission spectroscopy to detect when etching of the silicon nitride is complete. In response to determining at step 410 that the desired amount of the silicon nitride layer has not been removed, the method 400 proceeds back to step 406 to perform another cycle of etching. In response to determining at step 410 that the desired amount of the silicon nitride layer has been removed, the method 400 ends.

The method 400 offers potential advantages in process efficiency by eliminating the need to perform a hydrogen treatment step in each cycle. This can reduce the overall process time and potentially improve throughput. However, the effectiveness of this approach depends on the retention of sufficient hydrogen on the silicon nitride surface after each plasma removal step, which may vary depending on specific process conditions and the number of cycles performed.

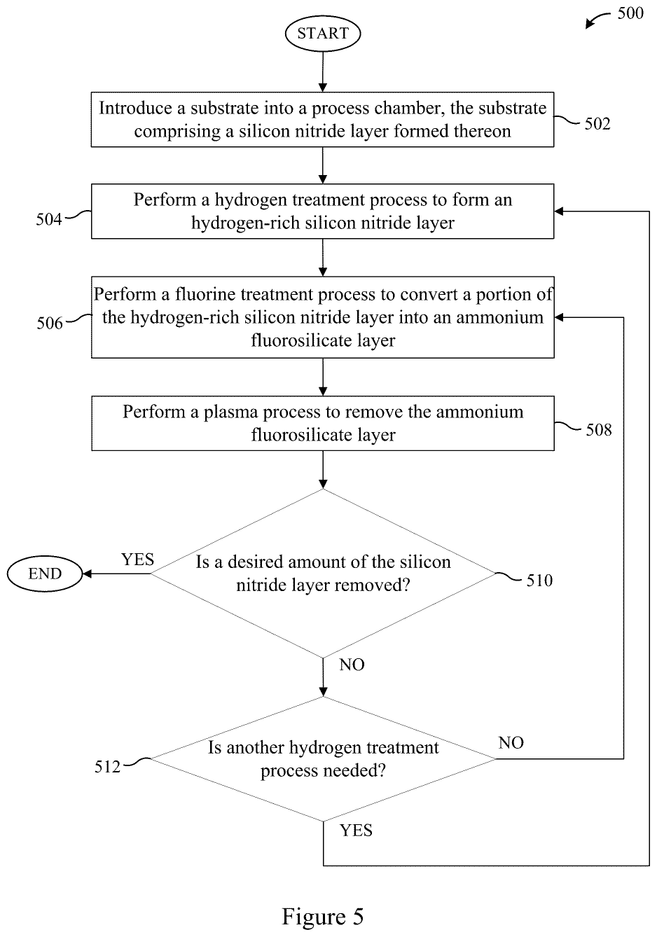

FIG. 5 illustrates a flow diagram of a method 500 for selectively etching a silicon nitride layer, in accordance with various embodiments. Although shown in a particular sequence, it should be appreciated that the steps of the method 500 may be performed in any suitable sequence.

In step 502, a substrate (e.g., substrate 102 of FIG. 1A) comprising a silicon nitride layer (e.g., dielectric layer 104 of FIG. 1A) formed thereon is introduced into a process chamber. The process chamber may be configured for various plasma processes and gas treatments, and may include components for temperature control, pressure regulation, and gas delivery.

In step 504, a hydrogen treatment process (e.g., hydrogen treatment process 108 of FIG. 1B) is performed on the silicon nitride layer to form a hydrogen-rich silicon nitride layer (e.g., hydrogen-rich layer 110 of FIG. 1C), as described above with refence to FIGS. 1B and 1C.

In step 506, a fluorine treatment process (e.g., fluorine treatment process 114 of FIG. 1D) is performed to convert a portion of the hydrogen-rich silicon nitride layer into an ammonium fluorosilicate layer (e.g., converted layer 116 of FIG. 1E), as described above with refence to FIGS. 1D and 1E. Step 506 is similar to step 306 in the method 300, with the distinction that only a portion of the hydrogen-rich silicon nitride layer is converted in each cycle, potentially allowing for multiple fluorine treatment cycles without requiring additional hydrogen treatment steps.

In step 508, a plasma process (e.g., plasma process 118 of FIG. 1F) is performed to remove the ammonium fluorosilicate layer, as described above with refence to FIGS. 1F and 1G.

In some embodiments, steps 504-508 may be performed in a same process chamber. In other embodiments, at least one of steps 504-508 may be performed in a deferent process chamber than the rest of steps 504-508.

In step 510, the method 500 determines whether a desired amount of the silicon nitride layer has been removed. The decision may be based on predetermined process recipes specifying a fixed number of cycles, or it may involve in-situ monitoring techniques such as optical emission spectroscopy to detect when etching of the silicon nitride is complete. In response to determining at step 510 that the desired amount of the silicon nitride layer has been removed, the method 500 ends. In response to determining at step 510 that the desired amount of the silicon nitride layer has not been removed, the method 500 proceeds to step 512.

In step 512, the method 500 determines whether another hydrogen treatment process is needed. This step may involve in-situ monitoring of the surface hydrogen content, for example using Fourier transform infrared spectroscopy (FTIR), to determine if the silicon nitride surface still has sufficient hydrogen to support selective HF adsorption. In response to determining at step 512 that another hydrogen treatment process is needed, the method 500 proceeds back to step 504 for another hydrogen treatment cycle. In response to determining at step 512 that another hydrogen treatment process is not needed, the method 500 proceeds back to step 506 for another fluorine treatment cycle.

The method 500 offers improved process efficiency by performing hydrogen treatment only when necessary, based on actual surface conditions rather than following a fixed recipe. This can provide advantages in both process time and precision, as it ensures that each fluorine treatment step has optimal conditions for selective adsorption while avoiding unnecessary processing steps.

Example embodiments of the disclosure are described below. Other embodiments can also be understood from the entirety of the specification as well as the claims filed herein.

Example 1. A method including: performing a hydrogen treatment process on a silicon nitride layer formed on a substrate, the hydrogen treatment process forming a hydrogen-rich silicon nitride layer; performing a fluorine treatment process to convert the hydrogen-rich silicon nitride layer into an ammonium fluorosilicate layer; and performing a plasma process to remove the ammonium fluorosilicate layer.

Example 2. The method of example 1, where performing the hydrogen treatment process includes performing an H₂ plasma process.

Example 3. The method of any of examples 1 and 2, where performing the fluorine treatment process includes performing a hydrogen fluoride (HF) treatment process.

Example 4. The method of example 3, where the hydrogen treatment process improves HF absorption on a surface of the silicon nitride layer.

Example 5. The method of any of examples 1 to 4, where performing the plasma process comprises performing an argon (Ar) plasma process.

Example 6. The method of any of examples 1 to 5, where the plasma process converts the ammonium fluorosilicate layer into volatile byproducts.

Example 7. The method of example 6, where the volatile byproducts comprise SiF₄, HF, or NH₃.

Example 8. A method including: performing a first hydrogen treatment process on a silicon nitride layer formed on a substrate, the first hydrogen treatment process forming a first hydrogen-rich silicon nitride layer; performing a first fluorine treatment process to convert a first portion of the first hydrogen-rich silicon nitride layer into a first ammonium fluorosilicate layer; performing a first plasma process to remove the first ammonium fluorosilicate layer; determining whether a second hydrogen treatment process is needed; and in response to determining that the second hydrogen treatment process is not needed: performing a second fluorine treatment process to convert a second portion of the first hydrogen-rich silicon nitride layer into a second ammonium fluorosilicate layer; and performing a second plasma process to remove the second ammonium fluorosilicate layer.

Example 9. The method of example 8, further including: in response to determining that the second hydrogen treatment process is needed: performing the second hydrogen treatment process on the silicon nitride layer to form a second hydrogen-rich silicon nitride layer; performing a third fluorine treatment process to convert a first portion of the second hydrogen-rich silicon nitride layer into a third ammonium fluorosilicate layer; and performing a third plasma process to remove the third ammonium fluorosilicate layer.

Example 10. The method of any of examples 8 and 9, where performing the first hydrogen treatment process includes performing an H₂ plasma process.

Example 11. The method of any of examples 8 to 10, where performing the first fluorine treatment process includes performing a hydrogen fluoride (HF) treatment process.

Example 12. The method of any of examples 8 to 10, where performing the first plasma process includes performing an argon (Ar) plasma process.

Example 13. The method of any of examples 8 to 12, where the first plasma process converts the first ammonium fluorosilicate layer into volatile byproducts.

Example 14. The method of any of examples 8 to 13, where the volatile byproducts comprise SiF₄, HF, or NH₃.

Example 15. The method of any of examples 8 to 14, where determining whether the second hydrogen treatment process is needed includes performing Fourier transform infrared spectroscopy to determine a hydrogen content of a surface of the silicon nitride layer.

Example 16. A method including: performing an etch process on a silicon nitride layer formed on a substrate, the etch process including one or more cycles, where a first cycle of the etch process includes: performing a hydrogen (H₂) plasma process on the silicon nitride layer to form a hydrogen-rich silicon nitride layer; performing a hydrogen fluoride (HF) treatment process to convert the hydrogen-rich silicon nitride layer into an ammonium fluorosilicate layer; and performing an argon (Ar) plasma process to remove the ammonium fluorosilicate layer.

Example 17. The method of example 16, where the hydrogen plasma process improves HF absorption on a surface of the silicon nitride layer.

Example 18. The method of any of examples 16 and 17, where the argon plasma process converts the ammonium fluorosilicate layer into volatile byproducts.

Example 19. The method of example 18, where the volatile byproducts includes SiF₄, HF, or NH₃.

Example 20. The method of one of examples 16 to 19, where the hydrogen plasma process, the hydrogen fluoride treatment process and the argon plasma process are performed in a same process chamber.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
performing a hydrogen treatment process on a silicon nitride layer formed on a substrate, the hydrogen treatment process forming a hydrogen-rich silicon nitride layer;
performing a fluorine treatment process to convert the hydrogen-rich silicon nitride layer into an ammonium fluorosilicate layer; and
performing a plasma process to remove the ammonium fluorosilicate layer.

2. The method of claim 1, wherein performing the hydrogen treatment process comprises performing an H₂ plasma process.

3. The method of claim 1, wherein performing the fluorine treatment process comprises performing a hydrogen fluoride (HF) treatment process.

4. The method of claim 3, wherein the hydrogen treatment process improves HF absorption on a surface of the silicon nitride layer.

5. The method of claim 1, wherein performing the plasma process comprises performing an argon (Ar) plasma process.

6. The method of claim 1,wherein the plasma process converts the ammonium fluorosilicate layer into volatile byproducts.

7. The method of claim 6, wherein the volatile byproducts comprise SiF₄, HF, or NH₃.

8. A method comprising:
performing a first hydrogen treatment process on a silicon nitride layer formed on a substrate, the first hydrogen treatment process forming a first hydrogen-rich silicon nitride layer;
performing a first fluorine treatment process to convert a first portion of the first hydrogen-rich silicon nitride layer into a first ammonium fluorosilicate layer;
performing a first plasma process to remove the first ammonium fluorosilicate layer;
determining whether a second hydrogen treatment process is needed; and
in response to determining that the second hydrogen treatment process is not needed:
performing a second fluorine treatment process to convert a second portion of the first hydrogen-rich silicon nitride layer into a second ammonium fluorosilicate layer; and
performing a second plasma process to remove the second ammonium fluorosilicate layer.

9. The method of claim 8, further comprising:
in response to determining that the second hydrogen treatment process is needed:
performing the second hydrogen treatment process on the silicon nitride layer to form a second hydrogen-rich silicon nitride layer;
performing a third fluorine treatment process to convert a first portion of the second hydrogen-rich silicon nitride layer into a third ammonium fluorosilicate layer; and
performing a third plasma process to remove the third ammonium fluorosilicate layer.

10. The method of claim 8, wherein performing the first hydrogen treatment process comprises performing an H₂ plasma process.

11. The method of claim 8, wherein performing the first fluorine treatment process comprises performing a hydrogen fluoride (HF) treatment process.

12. The method of claim 8, wherein performing the first plasma process comprises performing an argon (Ar) plasma process.

13. The method of claim 8, wherein the first plasma process converts the first ammonium fluorosilicate layer into volatile byproducts.

14. The method of claim 13, wherein the volatile byproducts comprise SiF₄, HF, or NH₃.

15. The method of claim 8, wherein determining whether the second hydrogen treatment process is needed comprises performing Fourier transform infrared spectroscopy to determine a hydrogen content of a surface of the silicon nitride layer.

16. A method comprising:
performing an etch process on a silicon nitride layer formed on a substrate, the etch process comprising one or more cycles, wherein a first cycle of the etch process comprises:
performing a hydrogen (H₂) plasma process on the silicon nitride layer to form a hydrogen-rich silicon nitride layer;
performing a hydrogen fluoride (HF) treatment process to convert the hydrogen-rich silicon nitride layer into an ammonium fluorosilicate layer; and
performing an argon (Ar) plasma process to remove the ammonium fluorosilicate layer.

17. The method of claim 16, wherein the hydrogen plasma process improves HF absorption on a surface of the silicon nitride layer.

18. The method of claim 16, wherein the argon plasma process converts the ammonium fluorosilicate layer into volatile byproducts.

19. The method of claim 18, wherein the volatile byproducts comprise SiF₄, HF, or NH₃.

20. The method of claim 16, wherein the hydrogen plasma process, the hydrogen fluoride treatment process and the argon plasma process are performed in a same process chamber.
